(19) United States
(12) Patent Application Publication
(10) Pub. No.: US 2002/0132491 A1
(43) Pub. Date: Sep. 19, 2002

(54) METHOD OF REMOVING PHOTORESIST MATERIAL WITH DIMETHYL SULFOXIDE

(76) Inventor: JOHN E. LANG, MILPITAS, CA (US)

Correspondence Address: HICKMAN STEPHENS AND COLEMAN LLP, P O BOX 52037, PALO ALTO, CA, 943030746

(21) Appl. No.: 09/274,194

(22) Filed: Mar. 22, 1999

Related U.S. Application Data
(60) Provisional application No. 60/114,493, filed on Dec. 31, 1998.

(51) Int. Cl. C23F 1/00; H01L 21/302; H01L 21/461

(52) U.S. Cl. 438/745

(57) ABSTRACT

A method of removing photoresist material from a semiconductor substrate includes providing a semiconductor substrate having a layer comprised of a low dielectric constant material and a layer comprised of photoresist material disposed over the layer comprised of the low dielectric constant material. The layer comprised of photoresist material is removed with dimethyl sulfoxide (DMSO). The layer of photoresist material is preferably removed by placing the semiconductor substrate in an ultrasonic bath containing DMSO in liquid form. The ultrasonic bath is preferably heated to at least about 50° C.

### CROSS REFERENCE TO RELATED APPLICATIONS

This application claims the benefit of co-pending U.S. Provisional Patent Application No. 60/114,493 filed on Dec. 31, 1998, which is incorporated herein by reference.

### BACKGROUND OF THE INVENTION

The present invention relates to semiconductor fabrication and, more particularly, to a method of removing a photoresist material from semiconductor wafers without damaging an underlying dielectric layer formed of a material having a low dielectric constant.

Integrated circuits use dielectric layers, which are typically made from silicon dioxide (SiO₂), to insulate conductive lines on various layers of a semiconductor structure. As the circuits become faster and more compact, operating frequencies increase and the distances between the conductive lines within the semiconductor device decrease. This introduces an increased level of coupling capacitance to the circuit, which has the drawback of slowing the operation of the semiconductor device. Therefore, it has become important to use dielectric layers that are capable of effectively insulating conductive lines against such increasing coupling capacitance levels.

In general, the coupling capacitance in an integrated circuit is directly proportional to the dielectric constant (K) of the material used to form the dielectric layers. As noted above, the dielectric layers in conventional integrated circuits are typically made from SiO₂, which has a dielectric constant of about 4.0. As a consequence of the increasing line densities and operating frequencies in semiconductor devices, dielectric layers formed of SiO₂ may not effectively insulate the conductive lines to the extent required to avoid increased coupling capacitance levels.

In an effort to reduce the coupling capacitance levels in integrated circuits, the semiconductor industry has engaged in research to develop materials having a dielectric constant lower than that of SiO₂ that are suitable for use in forming the dielectric layers in integrated circuits. To date, a number of promising materials, which are sometimes referred to as “low K materials,” have been developed.

During semiconductor wafer processing, features of the semiconductor device are defined in the wafer using well-known patterning and etching processes. In these processes a photoresist material is deposited onto the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove either the exposed regions (in the case of positive photoresist materials) or the unexposed regions (in the case of negative photoresist materials) of the photoresist material. Thereafter, the wafer is etched to remove the material from the areas that are no longer protected by the photoresist material and thereby define the desired features in the wafer.

After etching, the photoresist material, which is organic, is stripped from the wafer using a solvent, e.g., organic buffered sulfate (EKC). Problems have been experienced in the fabrication of semiconductor devices including dielectric layers formed of the low K materials developed to date, which are also organic, because the solvent attacks exposed portions of the dielectric layers during the photoresist stripping process. Such attack is undesirable because it denigrates the integrity of the dielectric layers and thereby impairs the ability of the dielectric layers to insulate effectively the metal lines in the semiconductor device. As discussed above, this causes increased coupling capacitance levels, which adversely affect the speed at which the semiconductor device operates. Despite the development of numerous low K materials and the growing need for semiconductor devices with dielectric layers formed of such materials, a reliable method for stripping photoresist material from a semiconductor wafer without damaging an underlying dielectric layer formed of a low K material is not available.

In view of the foregoing, what is needed is a reliable method for stripping photoresist material from semiconductor wafers without damaging underlying dielectric layers formed of low K materials.

### SUMMARY OF THE INVENTION

Broadly speaking, the present invention fills this need by providing a method for removing photoresist material from semiconductor substrates with a solvent that does not damage underlying dielectric layers formed of low dielectric constant materials. Several inventive embodiments of the present invention are described below.

In one embodiment of the present invention, a method of removing photoresist material from a semiconductor substrate is provided. In this method a semiconductor substrate having a layer comprised of a low dielectric constant material and a layer comprised of photoresist material disposed over the layer comprised of low dielectric constant material are first provided. The layer comprised of photoresist material is then removed with dimethyl sulfoxide. The low dielectric constant material preferably has a dielectric constant of about 3.0 or less and the dimethyl sulfoxide is preferably in liquid form.

In another embodiment of the present invention, a method of forming a semiconductor device is provided. In this method a semiconductor substrate is first provided. A layer comprised of a low dielectric constant material is then formed over the semiconductor substrate. Next, a layer comprised of photoresist material is formed over the layer comprised of the low dielectric constant material. The layer comprised of photoresist material is then patterned. Thereafter, the layer comprised of photoresist material is removed with dimethyl sulfoxide.

In yet another embodiment of the present invention, a method of removing photoresist material from a semiconductor substrate is provided. In this method a semiconductor substrate having a layer comprised of a low dielectric constant material disposed thereover and a layer comprised of photoresist material disposed over the layer comprised of the low dielectric constant material is first provided. The semiconductor substrate is then placed in an ultrasonic bath comprised of dimethyl sulfoxide in liquid form, wherein the dimethyl sulfoxide removes the layer comprised of photoresist material. The ultrasonic bath is preferably heated to at least about 50° C. The semiconductor substrate is preferably held in the ultrasonic bath for a period not longer than about 5 minutes.

The present invention advantageously enables semiconductor devices with dielectric layers formed of low K materials to be fabricated without damaging such dielectric layers during the fabrication process. This is important because, as line densities increase, dielectric layers formed of low K materials are needed to insulate effectively conductive lines and avoid increased coupling capacitance levels, which reduce the speed at which semiconductor devices operate.

These and other advantages of the present invention will become apparent to those skilled in the art upon reading the following detailed description of the invention and studying the accompanying drawings.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 is a cross-sectional view illustrating several layers of an exemplary semiconductor wafer during fabrication.

FIG. 2 illustrates the semiconductor wafer of FIG. 1 after development and removal of portions of the layer of photoresist material.

FIG. 3 illustrates the semiconductor wafer of FIG. 2 after an etching operation to define features of a semiconductor device.

FIG. 4 illustrates the semiconductor wafer of FIG. 3 after removal of the remaining portions of the layer of photoresist material.

### DETAILED DESCRIPTION OF THE PREFERRED EMBODIMENTS

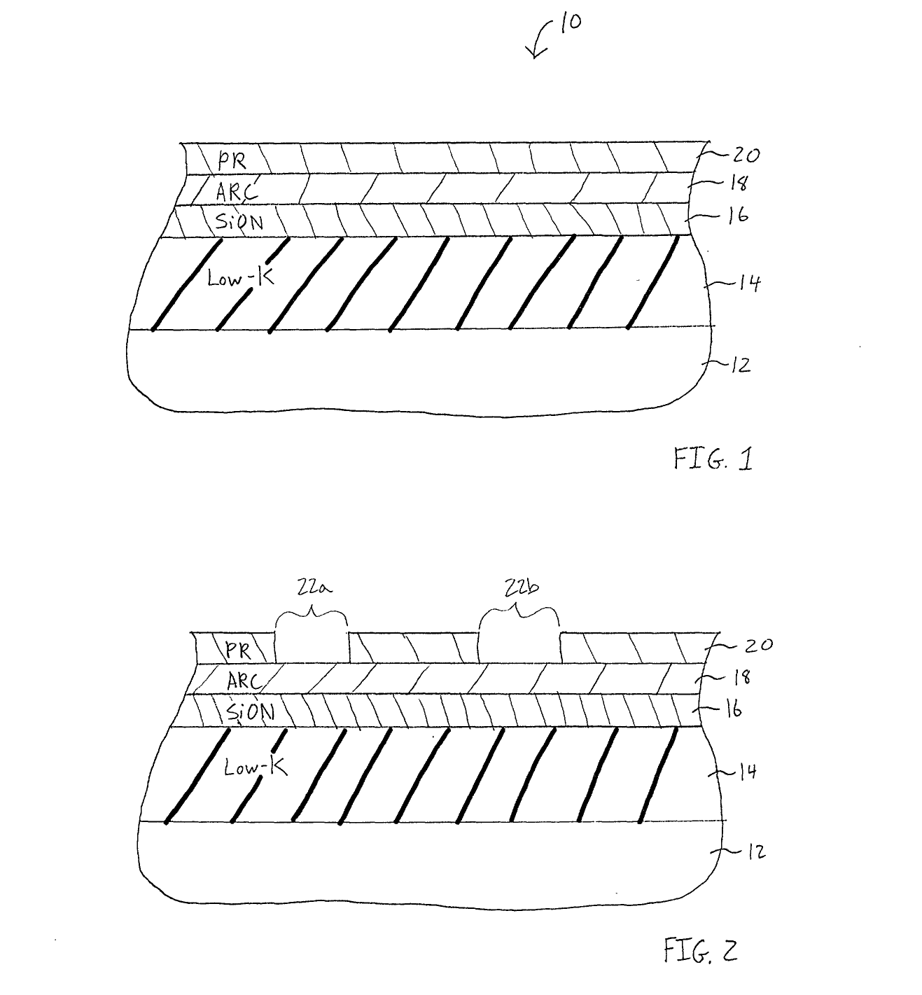

The methods of the invention will be described with reference to FIGS. 1-4, which illustrate certain process operations used to define features of a semiconductor device. In particular, FIGS. 1-4 illustrate patterning and etching operations used to define features of a semiconductor device including a dielectric layer formed of a low K material. Those skilled in the art will appreciate that the methods of the invention are not limited to the exemplary structure shown in FIGS. 1-4, but instead may be used to facilitate removal of photoresist material in any semiconductor device including a layer of dielectric layer formed of low K material.

FIG. 1 is a cross-sectional view illustrating several layers of a semiconductor wafer 10. The semiconductor wafer 10 includes a semiconductor substrate 12 formed of, e.g., silicon, that supports a dielectric layer 14 formed of a low K material. A hard mask layer 16 is disposed over dielectric layer 14. An anti-reflective coating (ARC) layer 18 is preferably disposed over hard mask layer 16. A layer of photoresist material 20 is then disposed over ARC layer 18.

Dielectric layer 14 may be formed of known low K materials in accordance with known techniques. As used in connection with the description of the invention, the term “low K material” means any material having a dielectric constant (K) lower than that of SiO₂, which has a dielectric constant of about 4.0. Representative low K materials include benzocyclobutene (BCB), FLARE, SiLK, parylene, and polytetrafluoroethylene (PTFE) such as GORE-TEX. SiLK is an organic material produced by Dow Corning Corporation of Midland, Mich. FLARE is an organic spin-on polymer formulated for use as a stand alone, low K interlayer dielectric produced by Allied Signal of Morristown, N.J.

At present, known low K materials suitable for use in semiconductor devices have a dielectric constant in a range of from about 1.5 to about 3.0. For example, BCB has a dielectric constant of about 2.6, SiLK has a dielectric constant of about 2.6, parylene has a dielectric constant of about 2.3, FLARE has a dielectric constant of about 2.8, and GORE-TEX has a dielectric constant of about 2.0. Those skilled in the art will appreciate that dielectric layer 14 may be made of other low K materials, including low K materials having a dielectric constant below about 1.5, as such materials become available.

Hard mask layer 16, which is typically made from silicon oxynitride (SiON), silicon nitrides (Si_{X}N_{Y}), SiO₂ (CVD) or tetraethcoxysilane (TEOS), generally has a thickness in the range from about 1 angstrom to about 5,000 angstroms to provide scratch protection for dielectric layer 14. Those skilled in the art are familiar with suitable techniques for forming hard mask layer 16.

ARC layer 18, which may be made from known organic materials, planarizes the surface of the wafer and aids in the patterning of small images by reducing the amount of light that is scattered. ARC layer 18 may be formed in accordance with known techniques, e.g., spinning and baking. The layer of photoresist material 20, which typically has a thickness of about 1 micron, may be made from known photoresist materials, which are typically organic. As is well known to those skilled in the art, the layer of photoresist material 20 is used in the patterning and etching operations to define the desired features of the semiconductor device.

FIG. 2 illustrates semiconductor wafer 10 after development and removal of portions of the layer of photoresist material 20. Before development of the photoresist material, portions of layer 20 are exposed to light filtered by a reticle. The light changes the structure and chemical properties of the photoresist material creating a number of polymerized photoresist sections. In the case of positive photoresist materials, these polymerized photoresist sections are then removed using a solvent in a development process creating openings 22a and 22b. For ease of illustration, only two openings 22 are shown, however; as is well known in the art, in actuality numerous openings 22 are created to provide access to the underlying layers for etching.

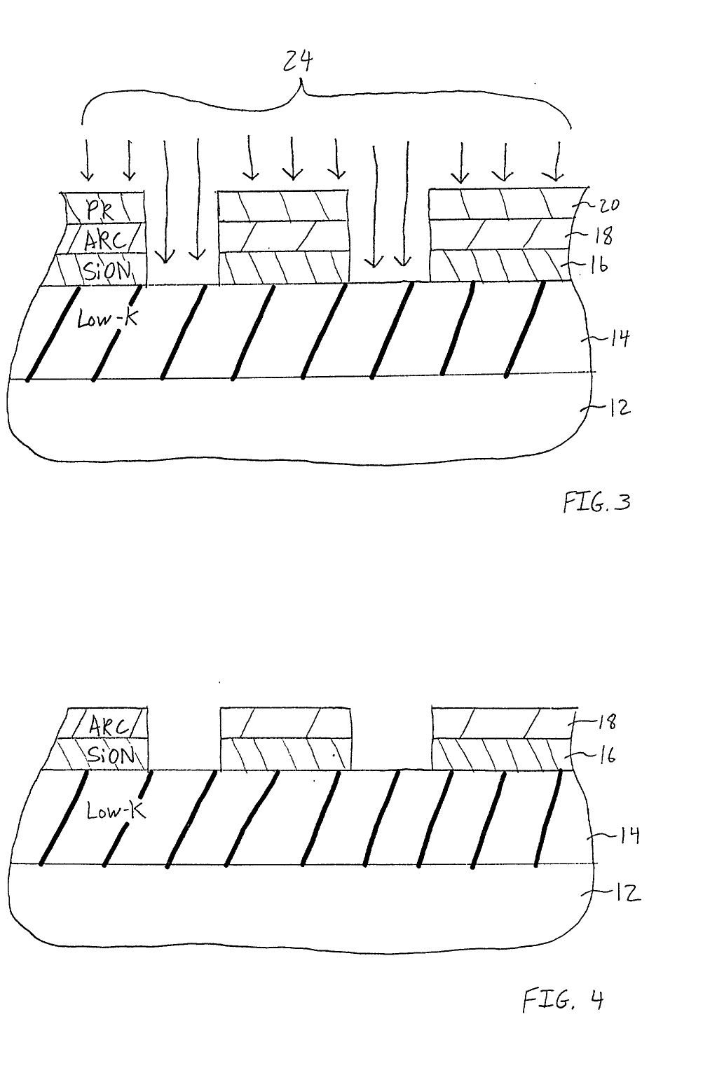

FIG. 3 illustrates semiconductor wafer 10 after etching to remove portions of ARC layer 18 and hard mask layer 16. In the etching operation etchant 24, which may be any suitable wet or dry etchant, completes the patterning of wafer 10 by first removing the portions of ARC layer 18 that are exposed by openings 22a and 22b (see FIG. 2), and then removing the exposed portions of hard mask layer 16. The remaining portions of the layer of photoresist material 20 protect the portions of ARC layer 18 and hard mask layer 16 covered thereby from etchant 24. The ideal etch operation leaves vertical sidewalls in the surface of semiconductor wafer 10 as shown in FIG. 3.

FIG. 4 illustrates semiconductor wafer 10 after the remaining portions of the layer of photoresist material 20 have been removed with dimethyl sulfoxide (DMSO) in accordance with the invention. In one embodiment of the invention, after an etching operation such as shown, for example, in FIG. 3, wafer 10 is placed in an ultrasonic bath comprised of DMSO in liquid form for stripping the layer of photoresist material 20. It has been found that DMSO, which is preferably of a high pressure liquid chromatography (HPLC) grade, removes the photoresist material by chemical dissolution but does not significantly damage either dielectric layer 14, hard mask layer 16, or ARC layer 18. In fact, optical measurements and SEM analysis have determined that there is no significant loss of the low K material during the stripping operation.

This result is surprising because the photoresist material and the low K material from which dielectric layer 14 is formed are both organic materials. In addition, in many instances, ARC layer 18 also may be an organic material. Thus, it has been discovered that DMSO unexpectedly exhibits selectivity toward low K materials in that it does not chemically attack such low K materials, whereas DMSO does chemically attack conventional photoresist materials. After the stripping operation is completed, wafer 10 may be removed from the ultrasonic bath and subjected to a suitable rinsing operation before subjecting the wafer to further processing.

In a preferred embodiment, the ultrasonic bath is preferably heated to a temperature of at least about 50° C., and more preferably to a temperature in the range from about 50° C. to about 60° C. Heating the bath shortens the amount of time required to strip the photoresist material from the wafer to a period substantially shorter than about 5 minutes and thereby helps increase throughput. In many instances, the time required to strip the photoresist material in such a heated ultrasonic bath might be as short as about 1 minute to about 2 minutes.

In the event the ultrasonic bath of DMSO is not heated, the time required to strip the photoresist material from the first wafer placed in such a bath may approach about 30 minutes. The time required for subsequent wafers will be substantially shorter, however, because the interaction between DMSO and the photoresist material generates heat that raises the temperature of the bath. Thus, under these circumstances, a second wafer may require only about 20 minutes for the stripping operation, a third wafer may require only about 10 minutes for the stripping operation, and a fourth and all subsequent wafers may require only about 5 minutes to about 6 minutes for the stripping operation.

Following the removal of the layer of photoresist material 20 using DMSO in accordance with the invention, wafer 10 may be subjected to further processing to provide, among other things, the electrical connections needed in a semiconductor device. Such processing may include, for example, the deposition of metallization lines and the formation of conductive vias to interconnect the metallization lines. Those skilled in the art are familiar with suitable techniques for depositing metallization lines and for forming conductive vias.

In summary, the present invention provides a method of removing photoresist material from a semiconductor wafer without damaging an underlying dielectric layer formed of a low K material. The invention has been described herein in terms of several preferred embodiments. Other embodiments of the invention will be apparent to those skilled in the art from consideration of the specification and practice of the invention. For example, it is believed that the method may be implemented using DMSO in gaseous form, although testing to confirm this belief has not been completed. Furthermore, certain terminology has been used for the purposes of descriptive clarity, and not to limit the present invention. The embodiments and preferred features described above should be considered exemplary, with the invention being defined by the appended claims.

What is claimed is:

1. A method of removing photoresist material from a semiconductor substrate, comprising:
providing a semiconductor substrate having a layer comprised of a low dielectric constant material disposed thereover and a layer comprised of photoresist material disposed over said layer comprised of said low dielectric constant material; and
removing said layer comprised of photoresist material with dimethyl sulfoxide.

2. The method of claim 1, wherein the low dielectric constant material has a dielectric constant of about 3.0 or less.

3. The method of claim 1, wherein the low dielectric constant material has a dielectric constant in the range from about 1.5 to about 3.0.

4. The method of claim 1, wherein the layer comprised of photoresist material is removed by subjecting the semiconductor substrate to dimethyl sulfoxide in liquid form.

5. The method of claim 4, wherein the semiconductor substrate is held in an ultrasonic bath.

6. The method of claim 5, wherein the ultrasonic bath is heated to at least about 50° C.

7. The method of claim 6, wherein the semiconductor substrate is held in the ultrasonic bath for a period not longer than about 5 minutes.

8. A method of forming a semiconductor device, comprising:
providing a semiconductor substrate;
forming a layer comprised of a low dielectric constant material over said semiconductor substrate;
forming a layer comprised of photoresist material over said layer comprised of said low dielectric constant material;
patterning said layer comprised of photoresist material; and
removing said layer comprised of photoresist material with dimethyl sulfoxide.

9. The method of claim 8, wherein the low dielectric constant material has a dielectric constant of about 3.0 or less.

10. The method of claim 8, wherein the low dielectric constant material has a dielectric constant in the range from about 1.5 to about 3.0.

11. The method of claim 8, wherein the layer comprised of photoresist material is removed by subjecting the semiconductor substrate to dimethyl sulfoxide in liquid form.

12. The method of claim 11, wherein the semiconductor substrate is held in an ultrasonic bath.

13. The method of claim 12, wherein the ultrasonic bath is heated to at least about 50° C.

14. The method of claim 13, wherein the semiconductor substrate is held in the ultrasonic bath for a period not longer than about 5 minutes.

15. A method of removing photoresist material from a semiconductor substrate, comprising:
providing a semiconductor substrate having a layer comprised of a low dielectric constant material disposed thereover and a layer comprised of photoresist material disposed over said layer comprised of said low dielectric constant material; and
placing said semiconductor substrate in an ultrasonic bath comprising dimethyl sulfoxide in liquid form, wherein said dimethyl sulfoxide removes said layer comprised of photoresist material.

16. The method of claim 15, wherein the low dielectric constant material has a dielectric constant of about 3.0 or less.

17. The method of claim 15, wherein the low dielectric constant material has a dielectric constant in the range from about 1.5 to about 3.0.

18. The method of claim 15, wherein the ultrasonic bath is heated to at least about 50° C.

19. The method of claim 18, wherein the semiconductor substrate is held in the ultrasonic bath for a period not longer than about 5 minutes.
